(19) United States
(12) Patent Application Publication
(10) Pub. No.: US 2023/0369045 A1
(43) Pub. Date: Nov. 16, 2023

(54) EPITAXIAL STRUCTURE HAVING INTEGRATED MICROCHANNELS

(71) Applicant: PALO ALTO RESEARCH CENTER INCORPORATED, Palo Alto, CA (US)

(72) Inventor: Thomas Wunderer, Santa Cruz, CA (US)

(21) Appl. No.: 17/744,535

(22) Filed: May 13, 2022

(51) Int. Cl. H01L 21/02; H01L 21/027; H01L 29/66; H01L 31/18; H01L 23/66

(52) U.S. Cl. CPC H01L 21/0254; H01L 21/02389; H01L 21/027; H01L 29/66431; H01L 31/1856; H01L 23/66; H01L 2223/6627

(57) ABSTRACT

An apparatus includes an epitaxial structure comprising a bottom layer, channel walls formed on the bottom layer, and a top layer that encloses the channel walls and forms microchannels therebetween. The bottom layer, channel walls, and covering layer are a monolithic, crystalline formation. An electronic or optoelectronic device is monolithically formed on a first build surface of the bottom layer or the top layer. The electronic or optoelectronic device is energy-coupled to the microchannels through the bottom layer or the top layer.

### SUMMARY

The present disclosure is directed to selective area epitaxy structures with integrated microchannels. In one embodiment, an apparatus includes an epitaxial structure comprising a bottom layer, channel walls formed on the bottom layer, and a top layer that encloses the channel walls and forms microchannels therebetween. The bottom layer, channel walls, and covering layer are a monolithic, crystalline formation. A first electronic or optoelectronic device is monolithically formed on a first build surface of one of the bottom layer or the top layer. The first electronic or optoelectronic device are energy-coupled to the microchannels through the bottom layer or the top layer.

These and other features and aspects of various embodiments may be understood in view of the following detailed discussion and accompanying drawings.

### BRIEF DESCRIPTION OF THE DRAWINGS

The discussion below makes reference to the following figures, wherein the same reference number may be used to identify the similar/same component in multiple figures.

FIG. 1 is a perspective cutaway view of an apparatus according to an example embodiment;

FIG. 2 is a cross-sectional view showing a microchannel used for heat pipes according to an example embodiment;

FIG. 3 is a cross-sectional view showing a microchannel used for a sample analyzer according to an example embodiment;

FIG. 4 is a cross-sectional view showing a microchannel used for a waveguide according to an example embodiment; and

FIGS. 5 and 6 are diagrams showing the formation of microchannels according to various embodiments; and

FIGS. 7 and 8 are flowcharts of methods according to example embodiments.

### DETAILED DESCRIPTION

The present disclosure is generally related to thin film semiconductor electrical, optical and mechanical structures. These structures are typically formed by depositing layers of materials onto a wafer (e.g., substrate or growth template) and patterned. The deposition and patterning of different materials is used to form electronic devices and circuits, opto-electronic and optical devices and circuits, micro-electromechanical systems, etc. In particular, this disclosure relates to epitaxial growth of structures, in which crystalline thin films are grown that follow the crystalline structure of the substrate.

Different methods can be used to shape structures during thin film wafer processing. One way to form thin-film structures is to pattern a photoresist or hard mask on a layer of material and then etch through parts of the underlying material not covered by the mask, e.g., using chemical wet etching or dry etching with ion bombardment, etc. This technique is commonly used to form conventional semiconductor-based devices and integrated circuits, for example. While effective for many uses, etching has some limitations. For example, etch-induced defects might result in non-radiative carrier recombination lowering device efficiency or the etched features might expose undesired surface roughness negatively impacting device performance.

In a process known as selective area growth (SAG) or selective area epitaxy (SAE), the lateral definition of the structures can be directly formed following a bottom-up approach. For that, a masking layer is typically deposited on the substrate or subsequent layers and patterned using standard lithographic techniques, e.g., photolithography. The mask material may be an amorphous dielectric film (e.g., SiO₂) that provides sufficient selectivity during the epitaxial growth process. This means the semiconductor material will only grow in the areas not covered by the masking material and allow diffusion of the relevant species from the masked areas to the openings. As the amount of deposited material grows, the part may adopt a geometry consistent with the crystalline structure of the material. In this way, very precisely shaped features can be created, and can result in a monolithic, crystalline structure offering atomically smooth surfaces.

Epitaxy is commonly used to form crystalline semiconductor films and heterostructures found in many electronic and optoelectronic devices. Selective area epitaxy can also be useful in forming micro- and nano-scale mechanical structures due to the precise geometric features that can be formed using this technique. For example, the present disclosure describes fabrication methods to form hollow micro- and nano-channels in crystalline semiconductor materials, such as GaN. For purposes of this disclosure, the micro- and nano-channels will be described as microchannels with the understanding that such term may also cover micrometer-scale and nanometer-scale channels.

The epitaxial structures with micro- and nano-channels can fulfill different functions based on the specific implementation with other electronic and optoelectronic components. For example, the micro- and nano-channels might be used for advanced thermal management schemes (e.g., heat pipes), as transport channel for chem-bio-medical analytes, or as hollow waveguide for electromagnetic waves (e.g., optical, radio frequency) with low absorption losses and desired dispersion properties. These methods provide a way to bring the micro- and nano-channels into close proximity (˜micron-scale) of the active elements of the actual device for improved performance or function. This can be hardly realized with alternative fabrication methods and is desirable as fully integrated solution for microdevices.

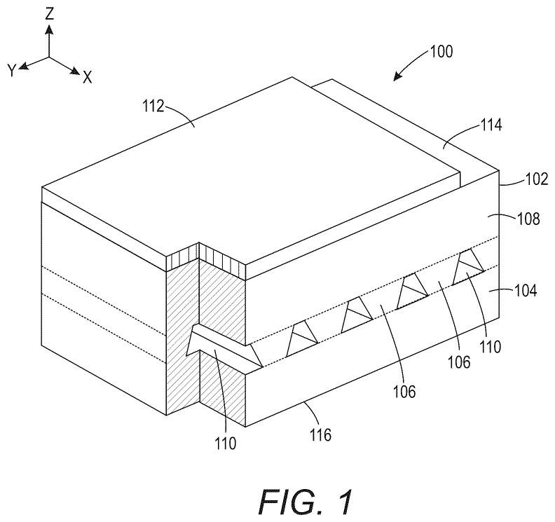

In FIG. 1, a perspective view shows an apparatus 100 according to an example embodiment. The apparatus 100 includes an epitaxial structure 102 that includes a bottom layer 104, channel walls 106 formed on the bottom layer 104, and a top layer 108 that encloses the channel walls 106 and forms microchannels 110 therebetween. Note that while the bottom layer 104, channel walls 106, and top layer 108 are shown as separate elements, they comprise a monolithic, crystalline formation. As described in detail below, different selective area epitaxy processing parameters may be used to form each of the layers.

An electronic or optoelectronic device element 112 may be monolithically formed on a first build surface 114 on top of layer 108. Alternatively or in addition, a second build surface 116 may be formed on the bottom layer 104, and a second electronic or optoelectronic device (not shown) may be integrated to this second build surface 116. For example, the bottom layer 104 may be deposited on the second electronic or optoelectronic device, or the apparatus 100 may be flipped over after building the first electronic or optoelectronic device 112 so that the second device can be created on build surface 116. The electronic or optoelectronic device 112 is energy-coupled to the microchannels 110 through the top layer 108, and the second electronic or optoelectronic device may be energy-coupled to the microchannels 110 through the bottom layer 104.

In one example, the apparatus 100 can address the problem of thermal heat management for electronics/optoelectronics. Generally speaking, electronics and optoelectronics can be managed at a system level using known conventional cooling schemes, e.g., cooling air forced through enclosures. Cooling at the chip level, however, remains a major bottleneck to the performance and reliability of electronics and optoelectronics devices. This is due to the local high-heat hot spots with a large on-chip temperature gradient and spatial constraints.

In applications such as high-power applications in electronics and optoelectronics (e.g., lasers, radio frequency amplifiers), insufficient heat management is currently one of the most limiting performance factors. The techniques described herein can provide a viable path for significant improvements. In particular, the microchannels 110 shown above can be used as heat pipes that are integrated into an electronic or optoelectronic component.

Micro-heat pipes, as they were first described by Cotter (T. P. Cotter, “Principles and prospects of micro-heat pipes,” 5th International Heat Pipe Conference, Tsukuba, Japan, 1984, pp. 328-334), are small ducts (usually with a triangular cross section) that are filled with a working fluid. Heat is transferred in the tube by the evaporation and condensation of the working fluid. In the evaporation region of the tube, the fluid vaporizes and the vapor travels to the cooled section of the tube and condenses. The condensed liquid collects in the corners of the duct, and capillary forces pull the liquid back to the evaporator region. The fluid is in a saturated state, so the temperature inside the tube is nearly isothermal.

There are demonstrators for chip-based micro-heat pipes in Si, for example, where the channels are etched into the semiconductor (V-shaped groove) and covered with a planar bonding wafer. The lithographic masking technique, coupled with an orientation-dependent etching technique, is typically utilized. Different channel shapes and cross sections have been evaluated. Generally speaking, a smaller interior angle cross sectional shape (e.g., starlike corners) can capture more capillary working fluid and, thus, remove the thermal load more effectively.

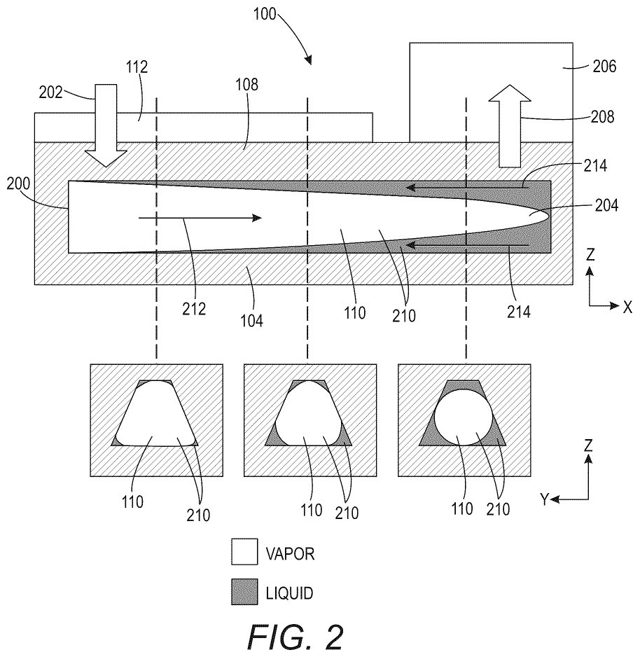

In FIG. 2, cross sectional views show features of a microchannel 110 when used as a micro heat pipe according to an example embodiment. At a first end 200 of the microchannel 110, the electronic or optoelectronic device 112 transfers heat 202 into the microchannel 110. At a second end 204 of the microchannel 110, a heat sink 206 transfers heat 208 out of the microchannel 110. Note that this process can be reversed, e.g., with a heat source replacing the heat sink 206, and the heat transfer going in the opposite direction to what is shown. The microchannel 110 can be formed similarly to any embodiments described herein, with dimensions and materials selected to have good performance in this application, e.g., high thermal conductivity, compatibility with the working fluid.

A heat transfer fluid 210 fills the microchannel 110. The heat transfer fluid 210 is illustrated using dark shading in a liquid state and without shading in a vapor state. The heat 202 input to the microchannel 110 at the first end 200 causes evaporation of the heat transfer fluid 210, the vapor resulting from the evaporation moving in direction indicated by arrow 212. The heat 208 removed from the microchannel 110 at the second end causes condensation of the heat transfer fluid 210, the liquid resulting from the condensation moving in direction indicated by arrows 214. As seen in the bottom cross-sectional views of FIG. 2, the liquid will move along the corners of the microchannel 110 due to capillary action.

In other embodiments, a single-phase flow could move through the microchannels for cooling. For example, a (dielectric) cooling fluid or gas could be pumped or otherwise circulated through the microchannels 110. In some embodiments, electric static field could be used to enhance circulation rate of a working fluid in the microchannels 110. For example, if magnetic particles were suspended in the working fluid, then an applied magnetic field could cause both the particles and fluid to move in a desired direction.

Benefits of micro-heat-pipes include: precise temperature control at the chip level; overall efficient cooling because specific heat sources within the electronic package may be targeted and reduce the contact thermal resistance; material compatibility with the electronic system; and large scale replication and mass production. For example, the device 112 that is cooled can be directly epitaxially grown onto a build surface that is part of the channel structure, leading to a very small distance between the device 112 and the coolant in the microchannels 110. Such a device 112 may include a high-electron-mobility transistor (HEMT) that is formed of materials compatible with the epitaxial structure 102 in which the microchannels 110 are formed, e.g., a AlGaInN compound.

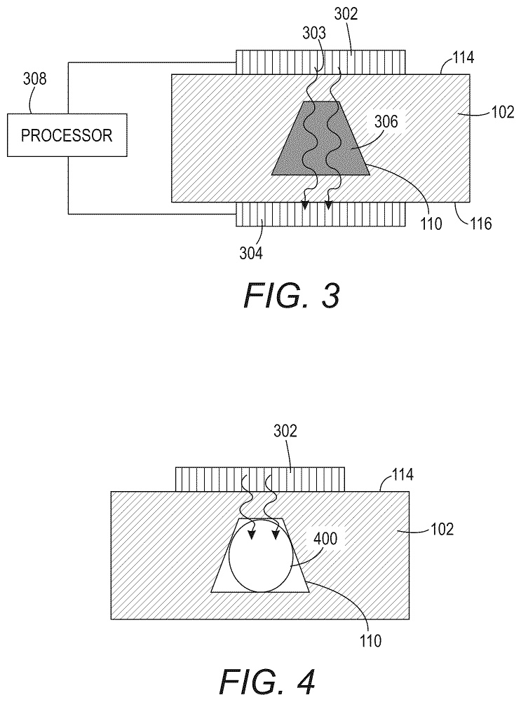

Another possible use for the micro- and nano-channels is to fully integrate the channels with electromagnetic emitters and detectors for micro-fluidic “lab-on-chip” applications. Being able to position (micro-)-emitters in close proximity to the fluidic or gaseous channels for localized and multiplexed excitation and detection is of great value. In FIG. 3, a cross-sectional view shows a lab-on-chip apparatus according to an example embodiment. The microchannel 110 can be formed similarly to other embodiments, however, it may have materials and dimensions that are selected to have desirable optical and fluidic properties in the surrounding layers, e.g., transparency at a wavelength of interest, compatible index of refraction, flow capacity, etc. Physical properties of the microchannel walls, such as shape and smoothness, may also be selected for favorable flow conditions, e.g., to reduce resistance to flow through the microchannel 110.

An emitter 302 (e.g., light emitter, microwave emitter, radio frequency emitter) is energy coupled to the microchannel 110 causing electromagnetic energy 303 to be transmitted through the epitaxial structure 102. A detector 304 (e.g., light detector, microwave detector, radio frequency detector) is energy coupled to microchannel 110 to detect the electromagnetic energy 303. An analyte 306 flows through the microchannel 110, and the emitter 302 and detector 304 are configured to perform an analysis on the analyte 306, e.g., via one or more processors 308 electrically coupled to the emitter 302 and detector 304. This may include a spectral analysis, which can detect frequencies/wavelengths of the electromagnetic energy 303 that are absorbed or emitted by the analyte 306. The analyte 306 may be any combination of a vapor and liquid, and may include solid particles flowing within the stream. The emitter 302 and detector 304 can be built on the top and bottom surfaces 114, 116 or vice versa. Alternatively, the epitaxial structure 102 can be formed onto one of the emitter 302 and detector 304, which serve as a build surface for the epitaxial structure 102.

In another implementation, microchannels 110 can used as a waveguide for electro-magnetic waves (e.g., in the optical or infrared spectral regime), shown in the cross-sectional view of FIG. 4. An electromagnetic transmitter or receiver 302 is shown formed on the top surface 114 of the epitaxial structure 102, which may be evanescently coupled to the waveguide. Alternatively, such a device may be located elsewhere, e.g., at an end of the microchannel 110. The microchannel 110 can be filled with a gas (e.g., air) or other material that is different than the material of the epitaxial structure 102. The characteristics of the microchannel 110, e.g., effective index of refraction, cross sectional size and shape, can be selected to efficiently propagate electromagnetic waves through the microchannel, as indicated by mode shape 400. If the electromagnetic transmitter or receiver 302 is a transmitter, a receiver, a detector or other energy receiving device (e.g., photovoltaic cell) may be coupled to the microchannel 110 elsewhere along its length or externally coupled from outside the epitaxial structure 102, e.g., via an optical fiber. Likewise, if the electromagnetic transmitter or receiver 302 is a receiver, then an emitting or transmitting device may be located coupled to the microchannel 110 elsewhere along its length or externally coupled from outside the epitaxial structure 102.

The benefits of using selective area epitaxy to form the microchannel waveguides include low losses due to low absorption (for a hollow waveguide) and scatter losses (atomically smooth surface via epitaxial growth). In addition, dispersion properties can be particularly advantageous for specific implementations. Coating the inner walls of the microchannel 110 with metal films can add additional benefits.

The benefits of using an epitaxially grown structure in the embodiments described above relate to the precision geometric features capable of being formed using processes such as selective area epitaxy. Generally speaking, micro-channels can be formed into semiconductor materials (e.g., Si) through lithographic patterning and etching steps, but are typically not (monolithically) integrated with other semiconductor device elements. In other words, today typically two (or more) components have to be individually fabricated and assembled (e.g., heat pipe+laser; or micro-fluidic chip+light emitting diode). In most cases, this results in length scales that are substantially larger than the ones in the proposed implementation (e.g., 100 μm-10 mm using etched channels vs. 100 nm-10 μm using selective area epitaxy) and, thus, cannot provide the desired functionality in device operation.

Commonly implemented thermal management solutions exhibit an elevated thermal resistance from using dissimilar materials and a thick thermal barrier. In the case of a micro-fluidic analysis chip, only one large light emitting diode (LED)/laser diode (LD) is typically used as excitation source and, thus, cannot provide highly efficient localized excitation without cross talk, undesired background illumination or excess heating. For the proposed embodiments described above, selective area epitaxy is used as means to form hollow micro- and nanochannels. Thus, closely spaced elements (e.g., an array of LEDs and detectors) can be fabricated and used without thermal, electrical, or optical barriers.

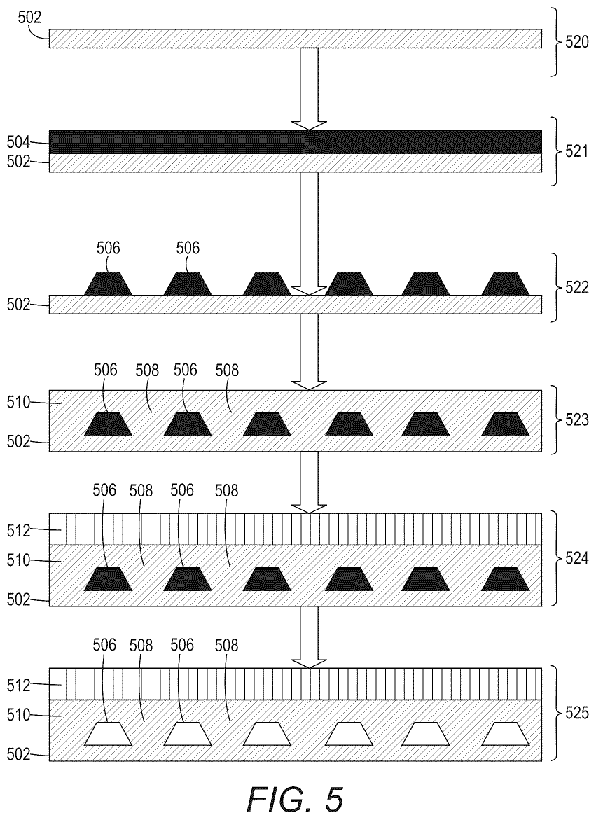

In FIG. 5, a diagram shows a method of forming microchannels in an epitaxial structure according to an example embodiment. In a first processing phase 520, a growth substrate or template 502 is prepared, which may include preparing a wafer with the desired properties and growing uniform epitaxial layers. The growth substrate or template 502 may include a GaN template on Al₂O₃(sapphire), Si, SiC, etc. A second processing phase 521 involves depositing a growth mask layer 504 (e.g., SiO₂, SiN) onto the growth substrate or template 502. At the next processing phase 522, the growth mask layer 504 is laterally patterned using (photo-)lithography and (dry) etching, such that masked areas 506 and mask-free regions are formed on the growth substrate or template 502. The masked areas 506 might be parallel longitudinal strips or follow any other segmented patterns suitable for the application, such as zig-zag patterns, an array of attached shapes, honeycomb pattern, random patterns, fractal patterns, etc.

At process phase 523, the wafer is reloaded into the growth reactor for epitaxial growth of the semiconductor materials. The channel walls 508 are grown between the longitudinal strips 506 of mask material and top layer 510 is laterally overgrown to cover the longitudinal strips 506. The process parameters may be different for growing the channel walls 508 and top layer 510. The process phase 523 may also involve, planarizing a top surface of the top layer 510.

At process phase 524, a heterostructure 512 of an electrical or optoelectrical device (LED, LD, HEMT, etc.) is grown on the top layer 510. The hollow microchannels 514 are formed at process phase 525. This process phase 525 may involve opening a fluid path to the longitudinal strips 506 and selectively etching (wet etching) the original growth mask material which leaves microchannels 514 through the surrounding material.

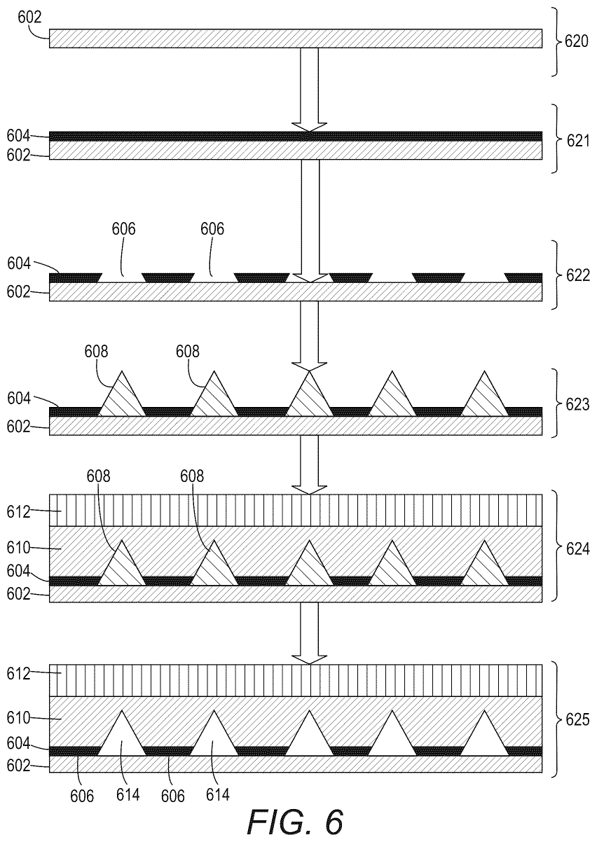

In FIG. 6, a diagram shows a method of forming microchannels in an epitaxial structure according to another example embodiment. In a first processing phase 620, a growth substrate or template 602 is prepared, which may include preparing a wafer with the desired properties and growing uniform epitaxial layers. The growth substrate or template 602 may include a GaN template on Al₂O₃(sapphire), Si, SiC, etc. A second processing phase 621 involves depositing a growth mask layer 604 (e.g., SiO₂, SiN) onto the growth substrate or template 602. The growth mask layer 604 is relatively thinner than growth mask layer 504 in FIG. 5.

At the next processing phase 622, the growth mask layer 604 is laterally patterned using (photo-)lithography and (dry) etching to form a striped or otherwise segmented (e.g., laterally segmented) mask pattern with voids/openings 606 that expose unmasked regions of the growth substrate or template 602. At process phase 623, the wafer is reloaded into the growth reactor for epitaxial growth of the semiconductor materials. Three-dimensional structures 608 are grown within the openings 606 of the growth mask layer 604. Note that the three-dimensional structures 608 are formed of a different material than the growth substrate or template 602 while still having a crystalline structure compatible with the growth substrate or template 602. The three-dimensional structures 608 may be differently doped (e.g., using Si) or may have a different band gap (e.g., GaInN) than the surrounding material(s). The three-dimensional structures 608 may have a crystal structure that results in a preferential growth pattern that defines, e.g., the angle of the structure's sides as seen in this view.

In processing step 624, the growth mask material 604 and growth mask layer 604 are laterally overgrown with top layer 610. The process phase 624 also involves planarizing a top surface of the top layer 610 and forming a heterostructure 612 of an electrical or optoelectrical device (LED, LD, HEMT, etc.) on the top layer 610. The hollow microchannels are formed at process phase 625. This may involve opening a channel to the three-dimensional structures 608 and selectively etching the material of the three-dimensional structures 608. The material for the three-dimensional structures 608 will be selected to have a different etch rate that the surrounding layers 602, 610. Selective etch rates can be achieved via different doping levels and/or differences in the semiconductor materials composition (e.g., AlGaN vs. GaN). These differences can result in different band gaps in the adjacent materials. Photo-enhanced chemical etching (PEC) and electrically biased etching could be used as fabrication techniques for realizing the desired selective etch conditions.

The embodiments described above may be implemented with numerous variations. For example, any group III-N compound can be used to form the top layer, bottom layer and channel walls, e.g., AlₓGa_{1-x-y}In_{y}N. In the embodiment shown in FIG. 6, the top layer, bottom layer and channel walls are formed from Alₓ₁Ga_{1-x1-y1}In_{y1}N and the three-dimensional sacrificial structure is formed of Alₓ₂Ga_{1-x2-y2}In_{y2}N, where x1≠x2 or y1≠y2. Alternatively, the material composition may be the same for the top layer, bottom layer, channel walls and three-dimensional sacrificial structure, but different doping levels (e.g., Si-doping of ˜10¹⁷-10²⁰ cm⁻³) may be implemented in the sacrificial structures to enhance the selectivity in etch rates. Note that while the microchannels shown in the figures above have trapezoidal and triangular cross sections, other cross-sectional shapes may be possible, such as rectangles, parallelograms, irregular quadrilaterals, pentagons. etc.

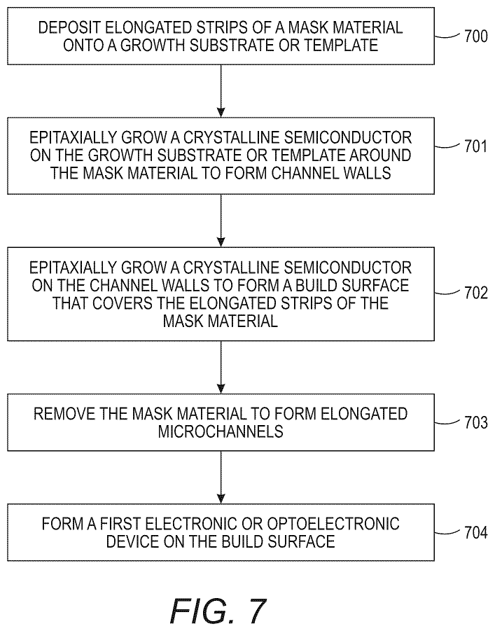

In FIG. 7, a flowchart shows a method according to an example embodiment. The method involves depositing 700 patterns (e.g., elongated strips or otherwise segmented areas) of a mask material onto a growth substrate or template. A crystalline semiconductor is epitaxially grown 701 on the growth substrate or template around the mask material to form channel walls. The crystalline semiconductor is epitaxially grown 702 on the channel walls to form a build surface that covers the elongated strips of the mask material. The mask material is removed 703 to form elongated microchannels. A first electronic or optoelectronic device is formed 704 on the build surface.

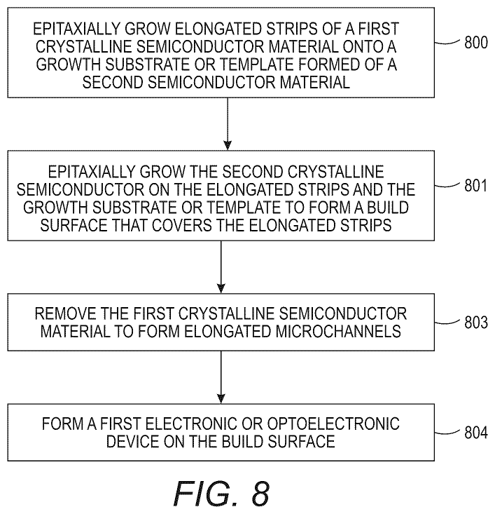

In FIG. 8, a flowchart shows a method according to another example embodiment. The method involves epitaxially growing 800 patterns (e.g., elongated strips or otherwise segmented sections) of a first crystalline semiconductor material onto a growth substrate or template formed of a second semiconductor material. The second crystalline semiconductor is epitaxially grown 801 on the elongated strips and the growth substrate or template to form a build surface that covers the elongated strips. The first crystalline semiconductor material is removed 802 to form elongated microchannels. A first electronic or optoelectronic device is formed 803 on the build surface.

In the embodiments shown in FIGS. 7 and 8, the growth substrate or template may include an electronic or optoelectronic device. In such a case, the formation of the first electronic or optoelectronic device in steps 704, 803 may be optional. The epitaxially growing in these methods may involve metalorganic vapor phase epitaxy. The removal 703 of the mask material may involve wet etching and the removal 802 of first crystalline semiconductor material may involve PEC and/or electrically biased etching.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein. The use of numerical ranges by endpoints includes all numbers within that range (e.g. 1 to 5 includes 1, 1.5, 2, 2.75, 3, 3.80, 4, and 5) and any range within that range.

The foregoing description of the example embodiments has been presented for the purposes of illustration and description. It is not intended to be exhaustive or to limit the embodiments to the precise form disclosed. Many modifications and variations are possible in light of the above teaching. Any or all features of the disclosed embodiments can be applied individually or in any combination and are not meant to be limiting, but purely illustrative. It is intended that the scope of the invention be limited not with this detailed description, but rather determined by the claims appended hereto.

1. An apparatus comprising:
an epitaxial structure comprising a bottom layer, channel walls formed on the bottom layer, and a top layer that encloses the channel walls and forms microchannels therebetween, the bottom layer, channel walls, and covering layer comprising a monolithic, crystalline formation; and
a first electronic or optoelectronic device monolithically formed on a first build surface of one of the bottom layer or the top layer, the first electronic or optoelectronic device being energy-coupled to the microchannels through the bottom layer or the top layer.

2. The apparatus of claim 1, wherein the energy coupling of the first electronic or optoelectronic device to the microchannels comprises heat transfer from the first electronic or optoelectronic device to a heat transfer fluid or gas in the microchannels.

3. The apparatus of claim 2, wherein the heat transfer fluid evaporates to a vapor in first part of the microchannels proximate the first electronic or optoelectronic device and condenses to a liquid in a second part of the microchannels away from the first electronic or optoelectronic device, wherein the liquid flows back to the first part of the microchannels via capillary forces.

4. The apparatus of claim 2, wherein the first electronic device comprises a high-electron-mobility transistor.

5. The apparatus of claim 1, further comprising a second electronic or optoelectronic device formed on a second build surface the epitaxial structure opposed to the first build surface, the second electronic or optoelectronic device being energy-coupled to the microchannels through the bottom layer or the top layer.

6. The apparatus of claim 5, wherein the first electronic or optoelectronic device comprises a light emitter optically coupled to the microchannels and the second electronic device comprises a light detector optically coupled to the microchannels, and wherein an analyte flows through the microchannels, and the light emitter and light detector are configured to perform a spectral analysis on the analyte.

7. The apparatus of claim 1, wherein the first electronic or optoelectronic device comprises an electromagnetic transmitter or receiver that is electromagnetically coupled to the microchannels, the microchannels configured as waveguides to propagate electromagnetic energy from or to the electromagnetic transmitter or receiver.

8. The apparatus of claim 1, wherein the epitaxial structure is formed from AlₓGa_{1-x-y}In_{y}N.

9. A method comprising:
depositing elongated strips or otherwise segmented pattern of a mask material onto a growth substrate or template;
epitaxially growing a crystalline semiconductor on the growth substrate or template around the mask material to form channel walls;
epitaxially growing the crystalline semiconductor on the channel walls to form a build surface that covers the elongated strips of the mask material;
removing the mask material to form elongated microchannels; and
forming a first electronic or optoelectronic device on the build surface.

10. The method of claim 9, wherein the mask material comprises a dielectric.

11. The method of claim 9, wherein the growth substrate or template comprises AlₓGa_{1-x-y}In_{y}N, and wherein the crystalline semiconductor comprises AlₓGa_{1-x-y}In_{y}N.

12. The method of claim 9, wherein the elongated strips or otherwise segmented sections of the mask material are patterned using lithography.

13. The method of claim 9, wherein the removing of the mask material is performed via wet etching.

14. The method of claim 9, wherein epitaxially growing the crystalline semiconductor on the growth substrate or template to form the channel walls and epitaxially growing the crystalline semiconductor to form the build surface comprises using metalorganic vapor phase epitaxy.

15. A method comprising:
epitaxially growing elongated strips or otherwise segmented sections of a first crystalline semiconductor material onto a growth substrate or template formed of a second semiconductor material;
epitaxially growing the second crystalline semiconductor on the elongated strips or otherwise segmented sections and the growth substrate or template to form a build surface that covers the elongated strips;
removing the first crystalline semiconductor material to form elongated microchannels; and
forming a first electronic or optoelectronic device on the build surface.

16. The method of claim 15, wherein epitaxially growing the elongated strips or otherwise segmented sections of the first crystalline semiconductor material onto the growth substrate or template comprises lithographically forming a striped mask pattern on the growth substrate or template, the elongated strips formed in voids of the striped mask pattern.

17. The method of claim 15, wherein the first and second crystalline semiconductor materials comprise a common chemical composition with different dopant levels.

18. The method of claim 17, wherein the common chemical composition comprises AlₓGa_{1-x-y}In_{y}N.

19. The method of claim 15, wherein the first and second crystalline semiconductor materials comprise a dissimilar chemical composition.

20. The method of claim 15, wherein the first crystalline semiconductor material comprises Alₓ₁Ga_{1-x1-y1}In_{y1}N and the second crystalline semiconductor material comprises Alₓ₂Ga_{1-x2-y2}In_{y2}N, where x₁≠x₂ or y₁≠y₂.
